(19) United States
(12) Patent Application Publication
(10) Pub. No.: US 2006/0124348 A1
(43) Pub. Date: Jun. 15, 2006

(54) Printed circuit board with insulative area for electrostatic discharge damage prevention

(75) Inventors: Yu-Xiang Wang, Shenzhen (CN); Hui-Zhang Wang, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/295,944

(22) Filed: Dec. 6, 2005

(30) Foreign Application Priority Data
Dec. 9, 2004 (CN) 200410077419.3

(51) Int. Cl. H05K 1/03

(52) U.S. Cl. 174/255; 174/262

(57) ABSTRACT

A printed circuit board for preventing electrostatic discharge damage includes several electronic components thereon. The printed circuit board defines several through holes therein, and includes a signal layer and a ground layer. The signal layer includes a central area and an edge area. The edge area encircles the central area and is separate from the central area. The electronic components are installed on the central area. An insulated area is formed between the central area and the edge area. In a typical application of the printed circuit board, screws are inserted into the through holes and engaged with a panel of a computer enclosure, thereby mounting the printed circuit board to the panel. Thus the edge area is absolutely grounded via the through holes. The electronic components are relatively grounded by connection to the ground layer.

### CROSS-REFERENCE TO RELATED APPLICATION

Related subject matter is disclosed in co-pending U.S. patent application entitled “PRINTED CIRCUIT BOARD WITH ELECTROSTATIC DISCHARGE DAMAGE PREVENTION,” which is assigned to the same assignee as that of the present application.

### BACKGROUND

1. Field of the Invention

The present invention relates to a printed circuit board for preventing electrostatic discharge damage, and more particularly to a printed circuit board achieving this without the need for substantial added materials.

2. General Background

In general, electronic products including printed circuit boards (PCBs) are susceptible to damage by electrostatic discharge during manufacturing, assembly, transportation and utilization. Therefore electrostatic discharge protection is necessary for electronic devices, especially printed circuit boards with sensitive components. The trend toward miniaturization of electronic components on printed circuit boards has lead to a reduction in compression and current surge resistance of electronic components. Therefore electrostatic fields and electrostatic currents from electrostatic discharges are more likely to damage precision electronic components on printed circuit boards. Damage resulting from an electrostatic discharge may impair the functioning of entire electronic devices.

Referring to FIG. 3 and FIG. 4, a conventional four-layer printed circuit board includes a signal layer 11, a power layer 15, a ground layer 17, and a plurality of electronic components 21. The printed circuit board defines a plurality of through holes 31 therein, and each through hole 31 has an electrical connection with the ground layer 17 through an inner wall of the through hole 31. Typically, the through holes 31 have metal coatings on the inner walls thereof. The electronic components 21 on the printed circuit board are connected to the ground layer 17 through pins and solder balls, so that the electronic components 21 can be grounded. The ground layer 17 can also provide EMI (Electro Magnetic Interference) shielding for the printed circuit board.

During the manufacture and assembly of printed circuit boards, electrical charges on the surface of an operator's body may be released through electrostatic discharge on contact with the printed circuit boards. The body of the operator commonly contacts an edge of the printed circuit board; therefore in general, the electrostatic discharge takes place on the edge of the printed circuit board. Because electrostatic current often discharges to the ground through a route which has a shortest distance and minimal impedance, the electrostatic current flows to the through holes 31 from the edge of the printed circuit board, and in doing so passes through one or more of the electronic components 21 on the printed circuit board. The electrostatic current may thereby damage the electronic components 21.

There are many means for preventing damage from electrostatic discharge on a printed circuit board. A common means is to design a protective circuit on the printed circuit board. However, in designing a protective circuit, each component's function and position on the printed circuit board should be considered. Additionally, a protective circuit requires additional electronic components and layout spaces on the printed circuit board. Furthermore, this kind of design is complex and increases the cost of manufacturing.

What is needed is a printed circuit board which can prevent damage due to electrostatic discharge without costly additions.

### SUMMARY

An exemplary printed circuit board for preventing electrostatic discharge damage includes several electronic components thereon. The printed circuit board defines several through holes therein, and includes a signal layer and a ground layer. The signal layer includes a central area and an edge area. The edge area encircles the central area and is separate from the central area. The electronic components are installed on the central area. An insulated area is formed between the central area and the edge area. In a typical application of the printed circuit board, screws are inserted into the through holes and engaged with a panel of a computer enclosure, thereby mounting the printed circuit board to the panel. Thus the edge area is absolutely grounded via the through holes. The electronic components are relatively grounded by connection to the ground layer.

When electrostatic discharge takes place due to an operator's touching of an edge of the printed circuit board, electrostatic charges flow to the panel through the through holes. That is, the electrostatic charges discharge to the absolute ground, instead of flowing to the ground layer. Thus, the electronic components on the central area of the printed circuit board are protected from damage due to electrostatic discharge.

Other advantages and novel features will become more apparent from the following detailed description when taken in conjunction with the accompanying drawings, in which:

### BRIEF DESCRIPTION OF THE DRAWINGS

FIG. 1 is a top plan view of a printed circuit board in accordance with a preferred embodiment of the present invention, showing the structure of a signal layer thereof and a layout of electronic components thereon;

FIG. 2 is a cross-sectional view of part of a conventional four-layer printed circuit board including a signal layer; and

FIG. 3 is a top plan view of the printed circuit board of FIG. 2, showing the signal layer together with electronic components and through holes thereat.

### DETAILED DESCRIPTION OF THE EMBODIMENTS

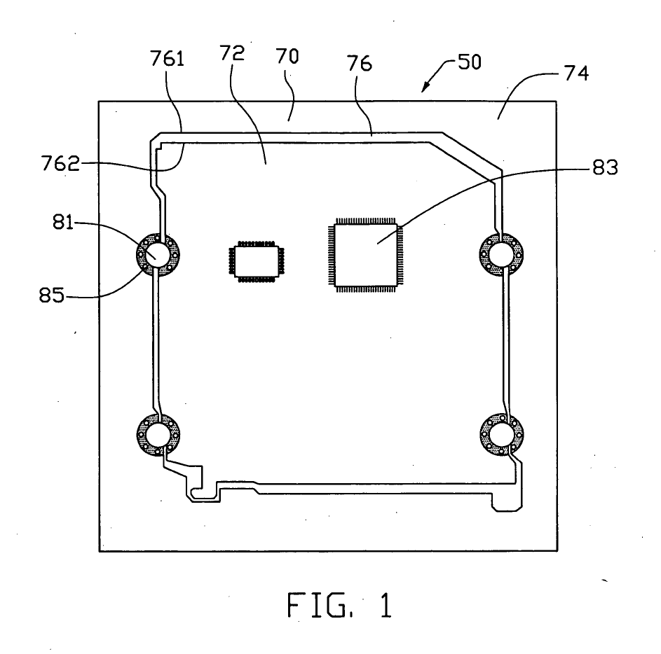

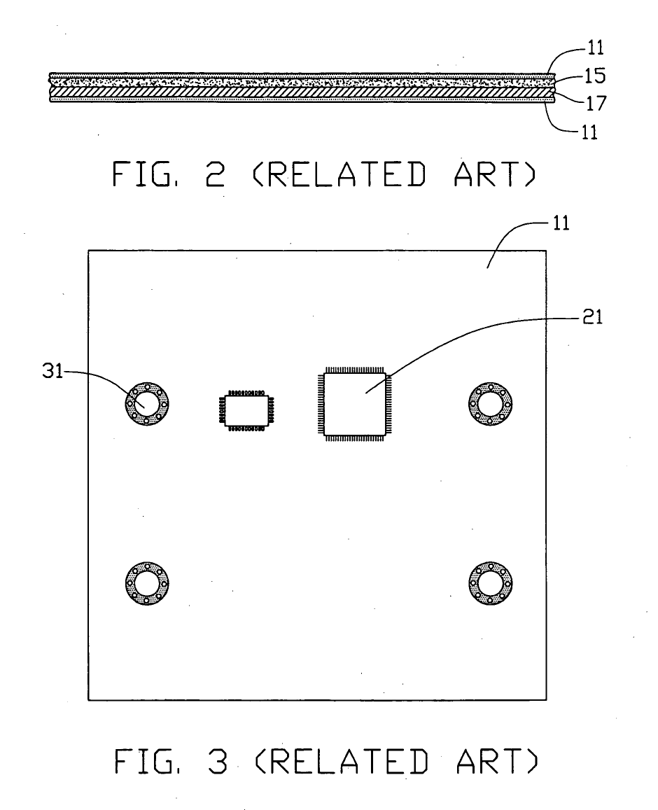

Referring to FIG. 1, this shows a printed circuit board 50 in accordance with a preferred embodiment of the present invention. The printed circuit board 50 defines a plurality of through holes 81 therein as a grounding means thereof. Typically, each of the through holes 81 has a metal coating on an inner wall thereof. The printed circuit board 50 comprises a signal layer 70 on one main side thereof, and a ground layer (not shown). A plurality of electronic components 83 is installed on a central region of the signal layer 70. The through holes 81 are defined in marginal positions of the signal layer 70. To protect the electronic components 83 from electrostatic discharge, the signal layer 70 of the printed circuit board 50 is designed according to a layout of the electronic components 83 on the printed circuit board 50. The signal layer 70 includes a central area 72 and an edge area 74. The electronic components 83 are installed on the central area 72. The edge area 74 encircles the central area 72 and is separate from the central area 72. An insulated area 76 is a stripe area formed between the central area 72 and the edge area 74, in order to cut off electrical connection between the central area 72 and the edge area 74. The insulated area 76 is formed by etching, and is filled with insulating material. Two opposite conductive sidewalls 761 and 762 enclose the insulated area 76. The insulated area 76 crosses the through holes 81. A width of the insulated area 76 is narrower than a diameter of each through hole 81. The width of the insulated area 76 is preferably about 5-10 mil (0.125-0.25 mm). In a typical application of the printed circuit board 50, screws (not shown) are inserted into the through holes 81 and engaged with a panel of a computer enclosure (not shown), thereby mounting the printed circuit board 50 to the panel. Thus the edge area 74 is absolutely grounded. The electronic components 83 are relatively grounded, in that they are connected to the ground layer.

The printed circuit board 50 defines a plurality of vias 85 around the through holes 81, which can enhance the grounding effect of the through holes 81. When electrostatic discharge takes place due to an operator's touching of an edge of the printed circuit board 50, electrostatic charges flow to the computer enclosure through the through holes 81 and discharge to the absolute ground, instead of flowing to the ground layer. Thus, the electronic components 83 on the central area 72 of the printed circuit board 50 are protected from damage due to electrostatic discharge. The printed circuit board 50 can prevent electrostatic discharge without costly additions. The principles of the present invention can be applied to a four-layer printed circuit board and also a six-layer printed circuit board.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments.

What is claimed is:

1. A printed circuit board for preventing electrostatic discharge damage to one or more electronic components arranged thereon, the printed circuit board comprising:
at least one through hole; and
a signal layer comprising:
a central area for accommodating the electronic components;
an edge area circling the central area; and
an insulated area between the central area and the edge area, the insulated area crossing the through hole.

2. The printed circuit board as claimed in claim 1, wherein the signal layer is on one main side of the printed circuit board.

3. The printed circuit board as claimed in claim 1, wherein the printed circuit board is a four-layer circuit board.

4. The printed circuit board as claimed in claim 1, wherein the printed circuit board is a six-layer circuit board.

5. The printed circuit board as claimed in claim 1, wherein a width of the insulated area is less than a width of the through hole.

6. The printed circuit board as claimed in claim 1, wherein the insulated area has two opposite conductive sidewalls.

7. A printed circuit board for preventing electrostatic discharge damage, the printed circuit board comprising:
a plurality of through holes; and
a signal layer comprising:
a central area for accommodating a plurality of electronic components thereon; and
an insulated area encircling the central area and crossing the through holes, and having two opposite conductive sidewalls.

8. The printed circuit board as claimed in claim 7, wherein the signal layer is on one main side of the printed circuit board.

9. The printed circuit board as claimed in claim 7, wherein the printed circuit board is a four-layer circuit board.

10. The printed circuit board as claimed in claim 7, wherein the printed circuit board is a six-layer circuit board.

11. The printed circuit board as claimed in claim 7, wherein a width of the insulated area is less than a width of each of the through holes.

12. A circuit board capable of preventing components thereon from electrostatic discharge damage, comprising:
a grounding means of said circuit board;
an occupied area available for installation of components of said circuit board onto said circuit board; and
an electrically insulated area formed beside said occupied area and capable of electrically insulating said occupied area from other areas of said circuit board, and of electrically conducting unexpected electrostatic discharge from said other areas toward said grounding means.

13. The circuit board as claimed in claim 12, wherein said grounding means is a plurality of through holes to be grounded formed in said circuit board.

14. The circuit board as claimed in claim 12, wherein said occupied area is defined on a central area of a signal layer of said circuit board, and said electrically insulated area is substantially an encircling stripe area around said central area to separate said central area from an edge area of said signal layer defined as said other areas of said circuit board.

15. The circuit board as claimed in claim 14, wherein said electrically insulated area is etched from electrically insulating material onto said signal layer.
